(19) United States
(12) Patent Application Publication
(10) Pub. No.: US 2025/0385143 A1
(43) Pub. Date: Dec. 18, 2025

(54) SEMICONDUCTOR MODULE AND METHOD FOR MANUFACTURING SEMICONDUCTOR MODULE

(71) Applicant: FUJI ELECTRIC CO., LTD., Kanagawa (JP)

(72) Inventor: Kazuma KAWAMURA, Matsumoto-city (JP)

(21) Appl. No.: 19/218,339

(22) Filed: May 25, 2025

(30) Foreign Application Priority Data
Jun. 14, 2024 (JP) 2024-096780

(51) Int. Cl. H01L 23/049; H01L 23/053; H01L 23/10

(52) U.S. Cl. CPC H01L 23/049; H01L 23/053; H01L 23/10

(57) ABSTRACT

Provided is a semiconductor module including: a housing portion which houses a semiconductor chip; at least one terminal which is electrically connected with the semiconductor chip; and a nut holding portion which includes a nut for coupling with the terminal and is inserted into the housing portion along a predetermined insertion direction. The nut holding portion may include a first narrow portion and a first wide portion which is provided on a side opposite to the insertion direction with respect to the first narrow portion and has a width greater than a width of the first narrow portion. The housing portion may include a locking portion which locks the nut holding portion by coming into contact with the first wide portion.

The contents of the following patent application(s) are incorporated herein by reference:
NO. 2024-096780 filed in JP on Jun. 14, 2024.

### BACKGROUND

### 1. Technical Field

The present invention relates to a semiconductor module and a method for manufacturing the semiconductor module.

### 2. Related Art

Patent Document 1 describes “a semiconductor module capable of preventing a sealing material from scattering and adhering to a terminal portion of an external terminal when a gas generated when the sealing material is cured escapes to an outside of the semiconductor module through an external terminal hole or the like”, Patent Document 2 describes “after an air inside the case 5 is discharged by an device (not illustrated) via the valve 15, an insulating gas is sealed in the space 13 of the case 5”, and Patent Document 3 describes “a semiconductor device having a nut globe and an independent terminal”.

### PRIOR ART DOCUMENTS

### Patent Documents

Patent Document 1: Japanese Patent Application Publication No. 2019-102553
Patent Document 2: Japanese Patent Application Publication No. 2003-152122
Patent Document 3: International Publication No. 2013/015031

### BRIEF DESCRIPTION OF THE DRAWINGS

FIG. 1A illustrates an example of a top view of a semiconductor module 100.

FIG. 1B illustrates an example of an XZ cross section of the semiconductor module 100 taken along line a-a′ in FIG. 1A.

FIG. 1C illustrates an example of a YZ cross section of the semiconductor module 100 taken along line b-b′ in FIG. 1A.

FIG. 2 illustrates an example of an enlarged view of a vicinity of a region A in FIG. 1A.

FIG. 3A is an enlarged view of a peripheral region of a terminal 530 in a semiconductor module 500 according to a comparative example.

FIG. 3B is an enlarged view of a peripheral region of a terminal 30 in the semiconductor module 100 of the present example.

FIG. 4A illustrates a modification of the enlarged view of the vicinity of the region A in FIG. 1A.

FIG. 4B illustrates a modification of the enlarged view of the vicinity of the region A in FIG. 1A.

FIG. 5 illustrates a positional relationship between the terminal 30 and a nut holding portion 40.

FIG. 6 is a perspective view of a semiconductor module 200 according to a modification.

FIG. 7 illustrates an example of a flowchart of a method for manufacturing the semiconductor module 100.

FIG. 8 illustrates an example of an upper surface in step S130.

### DESCRIPTION OF EXEMPLARY EMBODIMENTS

Hereinafter, embodiments of the present invention will be described. However, the following embodiments are not for limiting the invention according to the claims. In addition, not all combinations of features described in the embodiments are essential to a solution of the invention.

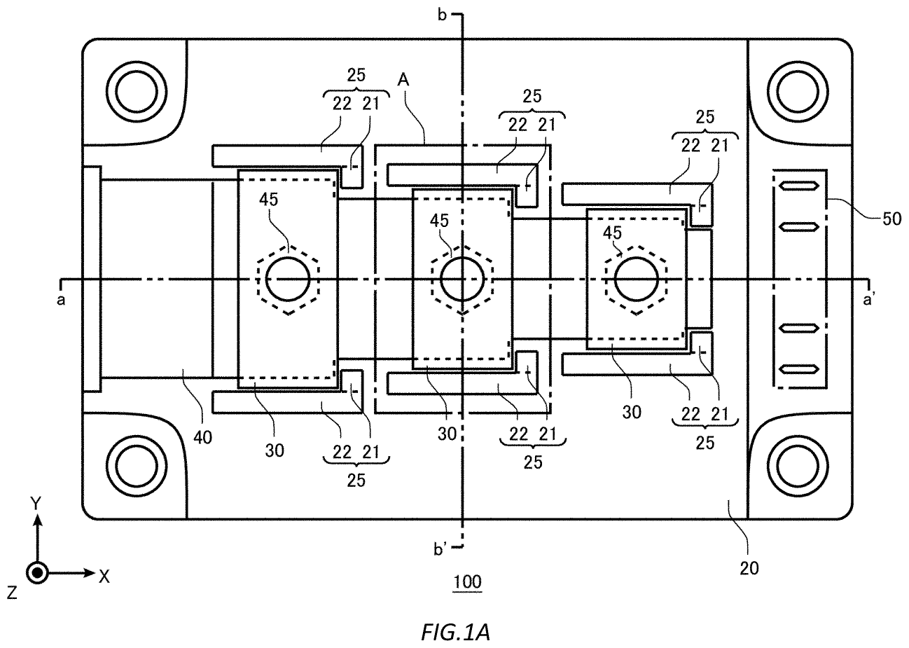

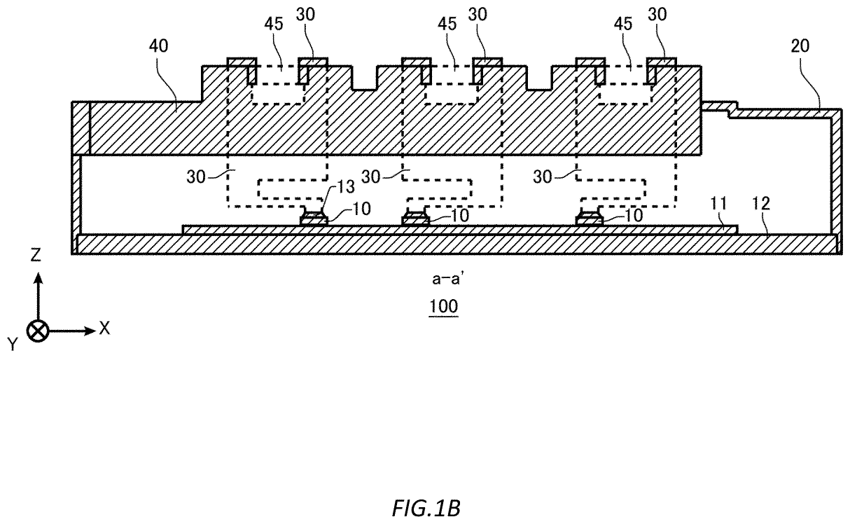

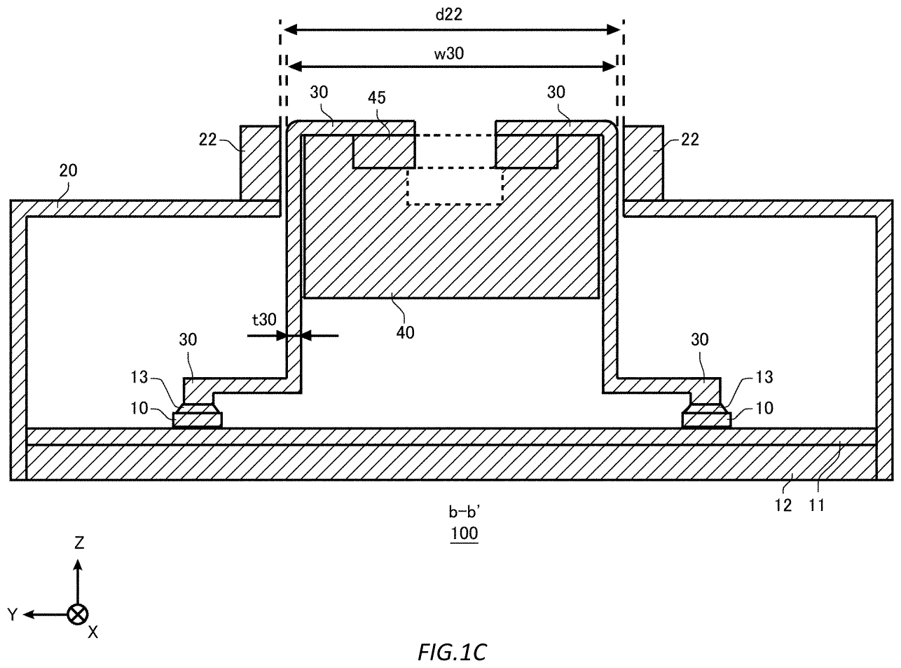

FIG. 1A is an example of a top view of the semiconductor module 100. The semiconductor module 100 of the present example includes a housing portion 20, a terminal 30, a nut holding portion 40, and an external connection terminal 50. The housing portion 20 includes a locking member 25 including a locking portion 21 and a main body 22.

The housing portion 20 houses a semiconductor chip 10 described later. The housing portion 20 may house a plurality of semiconductor chips 10. The housing portion 20 of the present example is provided in a substantially rectangular shape in top view. As used herein, a direction along a long side of the housing portion 20 is described as an X axis, a direction along a short side of the housing portion 20 is described as a Y axis, and a height direction of the housing portion 20 is described as a Z axis.

The terminal 30 is electrically connected with the semiconductor chip 10. The semiconductor module 100 of the present example includes at least one terminal 30. The semiconductor module 100 may include a plurality of terminals 30. The semiconductor module 100 of the present example includes three terminals 30. The terminal 30 may be a main terminal or an auxiliary terminal of the semiconductor module 100. The terminal 30 may be a collector terminal or an emitter terminal.

The nut holding portion 40 is inserted into the housing portion 20 along a predetermined insertion direction. As used herein, the predetermined insertion direction is an X-axis positive direction as an example. The nut holding portion 40 includes a nut 45 for coupling with the terminal 30. A specific configuration and function of the nut holding portion 40 will be described later.

The external connection terminal 50 connects the semiconductor module 100 with an external device. The external connection terminal 50 may be provided along any side of the housing portion 20. The external connection terminal 50 of the present example is provided on a short side of the housing portion 20 on an X axis side. The external connection terminal 50 may be a gate terminal or an emitter terminal.

The locking member 25 is provided on at least one side of the terminal 30. The locking member 25 of the present example is provided on both sides of the terminal 30, but is not limited thereto. With the locking member 25 being provided on at least one side of the terminal 30, the terminal 30 and the nut holding portion 40 can be locked on the side where the locking member 25 is provided.

The locking portion 21 locks the nut holding portion 40. The locking portion 21 can lock the nut holding portion 40 by coming into contact with a first wide portion 142 (described later) of the nut holding portion 40. The locking of the nut holding portion 40 by the locking portion 21 will be described in detail with reference to another drawing.

The locking portion 21 may lock the terminal 30. In the semiconductor module 100 of the present example, the locking portion 21 is provided on an insertion direction side with respect to the terminal 30. In FIG. 1A, the “insertion direction side” refers to a positive side direction of the X axis, but is not limited thereto. As used herein, the term “insertion direction side” is used in conjunction with the nut holding portion 40 which is inserted into the housing portion 20, and in a case where, in a positional relationship with the nut holding portion 40, a position of one component is set as a reference, and another component is provided on a side in an advancing direction in which the nut holding portion 40 is inserted into the housing portion 20, the case is described that the another component is provided on the insertion direction side with respect to the one component.

Accordingly, it is possible to suppress movement of the terminal 30 in the insertion direction. The locking portion 21 can bring the terminal 30 and the nut 45 into positional alignment in the insertion direction by locking both the terminal 30 and the nut holding portion 40.

The main body 22 is connected to the locking portion 21 and is provided along the terminal 30. The locking member 25 includes the locking portion 21 and the main body 22, and is provided in an L shape in top view. The main body 22 may function as a guide for positioning when the terminal 30 is provided.

FIG. 1B illustrates an example of an XZ cross section of the semiconductor module 100 taken along line a-a′ in FIG. 1A. An example of a structure inside the semiconductor module 100 will be described with reference to FIG. 1B.

Note that, in FIG. 1B, only a configuration necessary for description of a connection relationship between the semiconductor chip 10 and the terminal 30 and description of the positional alignment between the terminal 30 and the nut 45 is illustrated, and illustration of a wiring structure or the like necessary for an operation of the semiconductor module 100 is omitted. The semiconductor module 100 may include a sealing resin for sealing the semiconductor chip 10, and may include a lead frame or the like for being connected with an external terminal.

The semiconductor chip 10 is housed inside the housing portion 20. The semiconductor chip 10 is provided on a substrate 11. The semiconductor chip 10 may be any semiconductor element such as a transistor such as an insulated-gate bipolar transistor (IGBT), a diode such as a freewheel diode (FWD), or a reverse conducting IGBT (RC-IGBT).

The housing portion 20 may house a plurality of semiconductor chips 10. The housing portion 20 of the present example houses three semiconductor chips 10. The plurality of semiconductor chips 10 may be a same type of semiconductor element, or may be different types of semiconductor elements. If necessary, the plurality of semiconductor chips 10 may be distinguished as a first semiconductor chip 10, a second semiconductor chip 10, or the like.

The substrate 11 is a conductive member having an arbitrary thickness in a Z axis direction and provided on an upper surface of a heat dissipation plate 12. The substrate 11 may include a direct copper bonding (DCB) substrate or an active metal brazing (AMB) substrate. The substrate 11 may include an insulating plate formed of a ceramic material such as alumina (Al₂O₃), aluminum nitride (AlN), or silicon nitride (Si₃N₄), a resin material such as epoxy, an epoxy resin material using the ceramic material as a filler, or the like. The substrate 11 may include a metal plate formed as a plate including a metal material such as copper and a copper alloy. The substrate 11 may be fixed to the heat dissipation plate 12 by soldering, brazing, or the like.

The heat dissipation plate 12 is provided at a bottom of the semiconductor module 100. A cooling device (not illustrated) such as a heat sink may be provided below the heat dissipation plate 12, and heat generated in the semiconductor module 100 during use of the semiconductor module 100 may be dissipated to an outside. The heat dissipation plate 12 may be applied with a thermal conductive material, such as thermal interface material (TIM), having an organic insulating property.

The terminal 30 is connected with the semiconductor chip 10 via a solder 13. The terminal 30 is made of a conductive metal material such as copper and a copper alloy. The terminal 30 may be formed by bending a single metal plate. In FIG. 1B, a portion of the terminal 30 that does not appear in the XZ cross section taken along line a-a′ is indicated by a dotted line.

When the semiconductor module 100 includes a plurality of terminals 30, the terminals 30 may be connected to a same semiconductor chip 10 or may be connected to different semiconductor chips 10. Inside the housing portion 20, a first terminal 30 may be connected to the first semiconductor chip 10, and a second terminal 30 may be connected to the second semiconductor chip 10. In the semiconductor module 100 of the present example, the plurality of terminals 30 are connected to different semiconductor chips 10. The terminal 30 may be connected to two or more semiconductor chips 10.

The terminal 30 and the nut 45 are brought into positional alignment by inserting the nut holding portion 40 into the housing portion 20. As used herein, the positional alignment between the terminal 30 and the nut 45 may mean alignment between an opening of a hole provided in the terminal 30 and an opening of a threaded hole of the nut 45. With the positional alignment between the terminal 30 and the nut 45, the external device and the semiconductor module 100 can be easily connected by fastening a power supply terminal of the external device with a screw.

When the semiconductor module 100 includes the plurality of terminals 30, the nut holding portion 40 may include the nuts 45 corresponding to the respective terminals 30. The nut holding portion 40 may include a first nut 45 for coupling with the first terminal 30 and may include a second nut 45 for coupling with the second terminal 30. The nut holding portion 40 of the present example includes three nuts 45 corresponding to the three terminals 30 included in the semiconductor module 100.

FIG. 1C illustrates an example of a YZ cross section of the semiconductor module 100 taken along line b-b′ in FIG. 1A. An example of a structure inside the semiconductor module 100 will be described with reference to FIG. 1C.

The terminal 30 of the present example is formed in an inverted U shape including an upper surface and a side surface in the YZ cross section. The terminal 30 may be formed to have a predetermined thickness t30. The predetermined thickness t30 may be thinner than a thickness of the nut 45. The thickness t30 may be equal to or greater than 0.5 mm and equal to or less than 1.0 mm. The terminal 30 in the present example has a thickness of 0.8 mm.

The terminal 30 of the present example is provided such that a width w30 exposed from an upper surface of the semiconductor module 100 is less than an interval d22 between the main bodies 22. The interval d22 between the main bodies 22 may be at least 5% and at most 50% of the width of the housing portion 20. In an example, the width w30 of the terminal 30 is equal to or greater than 18.2 mm and equal to or less than 23.6 mm, and the interval d22 between the main bodies 22 is equal to or greater than 20.2 mm and equal to or less than 25.6 mm. Accordingly, when the semiconductor chip 10 is housed in the housing portion 20, positional alignment can be made such that the terminal 30 comes between two main bodies 22.

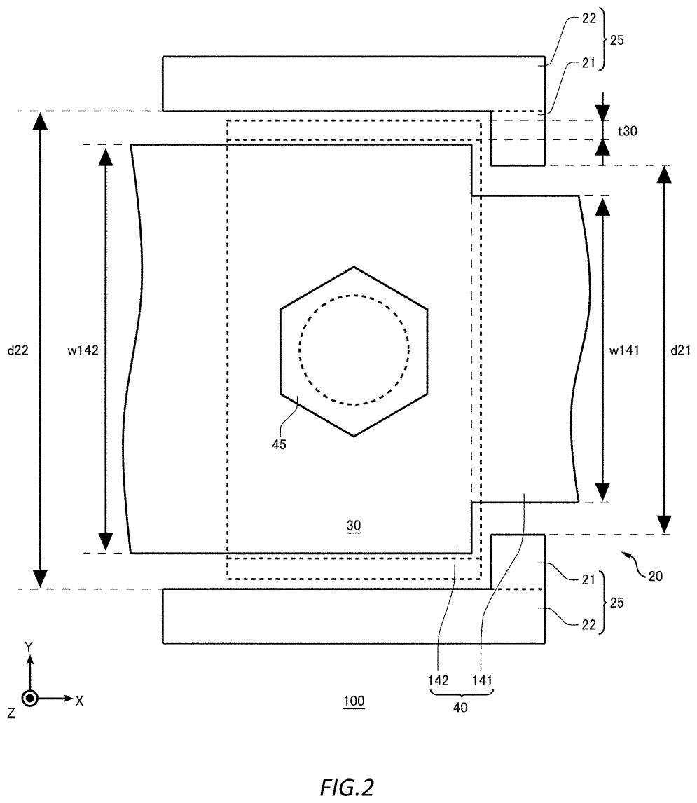

FIG. 2 is an example of an enlarged view of a vicinity of a region A in FIG. 1A. Shapes of the nut holding portion 40, the terminal 30, and the locking member 25 in the semiconductor module 100 of the present example and a positional relationship thereof will be described with reference to FIG. 2. Note that, although the terminal 30 is arranged on a foremost surface in top view, the terminal 30 is indicated by a dotted line for the sake of description.

The nut holding portion 40 includes a first narrow portion 141 and the first wide portion 142. The first narrow portion 141 in the present example has a predetermined width w141. The predetermined width w141 is less than an interval d21 between the locking portions 21. Accordingly, the nut holding portion 40 can be inserted into the housing portion 20 without interfering with the housing portion 20. The interval d21 between the locking portions 21 may be at least 5% and at most 50% of the width of the housing portion 20. In an example, the predetermined width w141 is equal to or greater than 15.5 mm and equal to or less than 20.9 mm, and the interval d21 between the locking portions 21 is equal to or greater than 15.7 mm and equal to or less than 21.1 mm.

The first wide portion 142 is provided on a side opposite to the insertion direction (a negative side in an X axis direction in FIG. 2) with respect to the first narrow portion 141, and has a width greater than that of the first narrow portion 141. The first wide portion 142 of the present example has a predetermined width w142. The width w142 of the first wide portion 142 may be at least 5% and at most 40% of the width w141 of the first narrow portion 141. The width w142 of the first wide portion 142 is less than the interval d22 between the main bodies 22 of the locking members 25 provided on both sides of the terminal 30 and greater than the interval d21 between the locking portions 21 of the locking members 25. Accordingly, the locking portion 21 can come into contact with the first wide portion 142 to lock the nut holding portion 40.

In the present example, the width w142 of the first wide portion 142 is greater than the interval d21 between the locking portions 21, and is less than a width (d22-2×t30) obtained by subtracting twice the thickness t30 of the terminal 30 from the interval d22 between the main bodies 22. Accordingly, while the nut holding portion 40 is locked by the locking portion 21, the nut holding portion 40 can be inserted into the housing portion 20 without interfering with the housing portion 20 and the terminal 30.

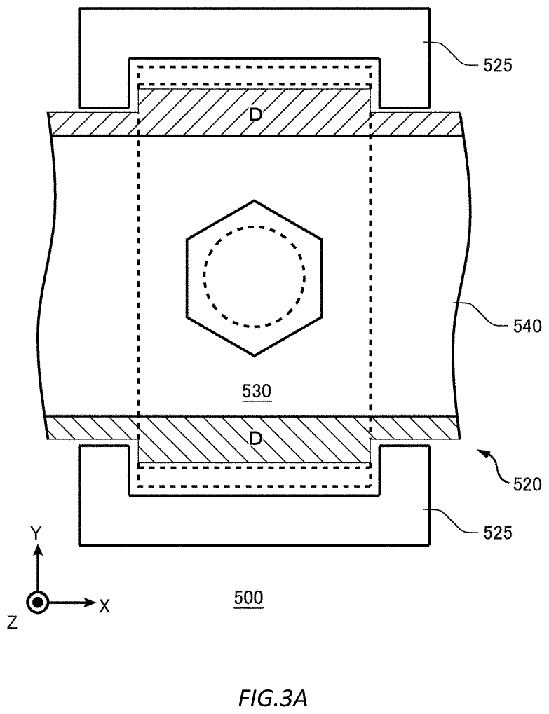

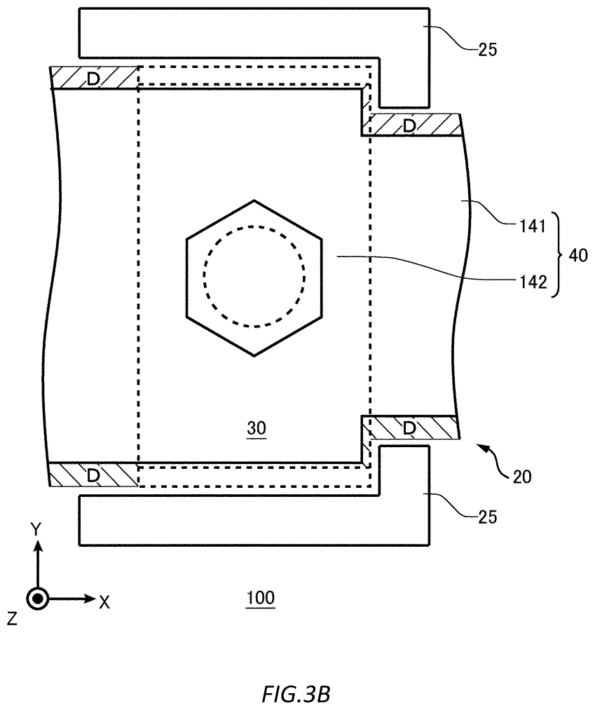

In the semiconductor module 100 of the present example, since the nut holding portion 40 includes the first narrow portion 141 and the first wide portion 142, a size of a groove formed between the housing portion 20 and the nut holding portion 40 can be reduced, and a corrosive gas can be prevented from entering an inside of the semiconductor module 100. Details will be described with reference to FIGS. 3A and 3B described later.

FIG. 3A is an enlarged view of a peripheral region of a terminal 530 in semiconductor module 500 according to a comparative example. In FIG. 3A, a housing portion 520, a locking member 525, the terminal 530, and a nut holding portion 540 are illustrated.

In the semiconductor module 500 of the comparative example, the nut holding portion 540 has a shape having a constant width, and does not include the first narrow portion 141 and the first wide portion 142. In the semiconductor module 500 of the comparative example, with such a structure, a groove D is formed between the housing portion 520 and the nut holding portion 540. In FIG. 3A, hatching is shown in the groove D formed between the housing portion 520 and the nut holding portion 540.

FIG. 3B is an enlarged view of a peripheral region of the terminal 30 in the semiconductor module 100 of the present example. In FIG. 3B, the housing portion 20, the locking member 25, the terminal 30, and the nut holding portion 40 are illustrated.

In the semiconductor module 100 of the present example, the nut holding portion 40 includes the first narrow portion 141 and the first wide portion 142. In addition, in the semiconductor module 100 of the present example, the locking member 25 is provided in an L shape in top view. In the present example, since the groove formed between the terminal 30 and the housing portion 20 can be filled with the first wide portion 142, a size of the groove D formed between the housing portion 20 and the nut holding portion 40 is reduced. Accordingly, the corrosive gas can be prevented from entering the inside of the semiconductor module 100, and a corrosion resistance of the semiconductor module 100 can be improved.

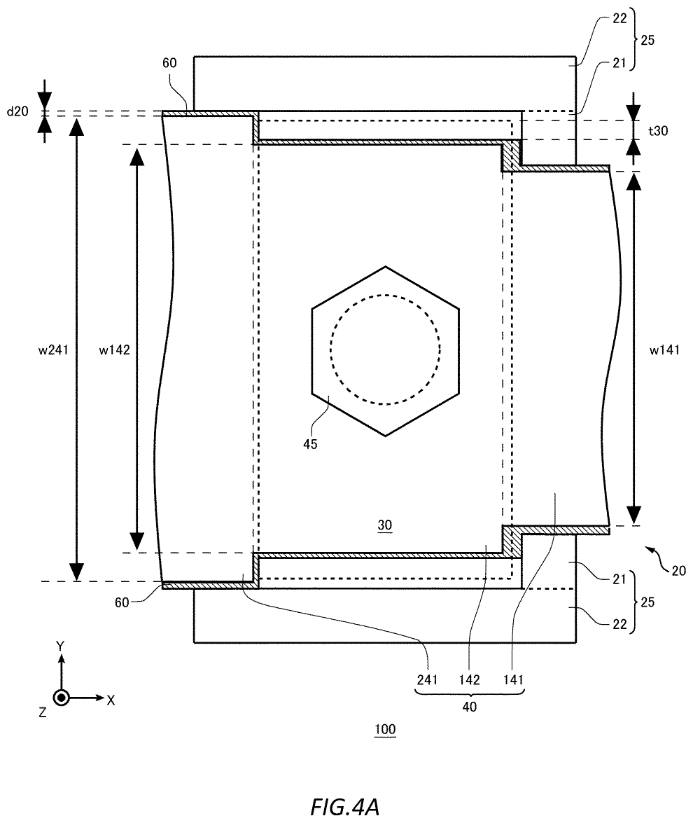

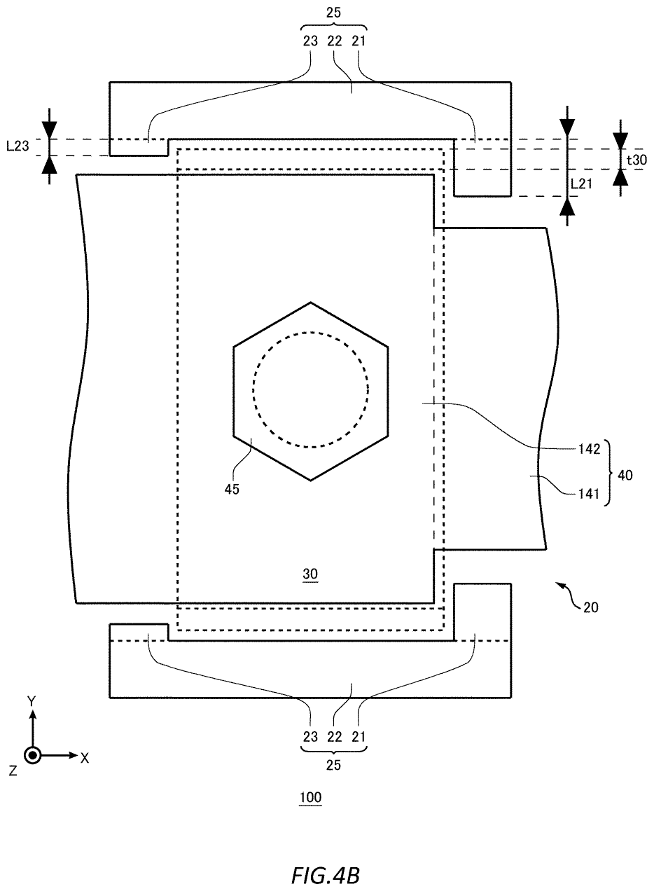

FIG. 4A is a modification of the enlarged view of the vicinity of the region A in FIG. 1A. Differences from FIG. 2 will be described with reference to FIG. 4A.

In the semiconductor module 100 of the present example, the nut holding portion 40 includes a second narrow portion 241. The second narrow portion 241 is provided on a side opposite to the insertion direction with respect to the first wide portion 142. That is, the second narrow portion 241 is provided on the negative side in the X axis direction with respect to the first wide portion 142.

In the semiconductor module 100 of the present example, the first wide portion 142 is arranged at a position corresponding to the terminal 30 in the insertion direction, and the second narrow portion 241 is arranged on a side opposite to the insertion direction with respect to the terminal 30 in the insertion direction. The first wide portion 142 may be provided at a position facing a side surface of the terminal 30 in a state where the nut holding portion 40 is inserted into the housing portion 20. The second narrow portion 241 may be provided at a position of an end portion of the terminal 30 on the negative side in the X axis direction in a state where the nut holding portion 40 is inserted into the housing portion 20.

In the semiconductor module 100 of the present example, the second narrow portion 241 has a predetermined width w241. The width w241 of the second narrow portion 241 is equal to or greater than the width w142 of the first wide portion 142. A difference between the width w241 of the second narrow portion 241 and the width w142 of the first wide portion 142 may be greater than 0 mm and equal to or less than the thickness t30 of the terminal 30. In an example, the predetermined width w241 is equal to or greater than 20.0 mm and equal to or less than 25.4 mm.

The width w241 of the second narrow portion 241 may be the same as the width w142 of the first wide portion 142, and may be greater than the width w142. In the semiconductor module 100 of the present example, the width w241 of the second narrow portion 241 is greater than the width w142 of the first wide portion 142. Accordingly, on the side opposite to the insertion direction with respect to the terminal 30, the size of the groove formed between the housing portion 20 and the nut holding portion 40 can be reduced to improve the corrosion resistance of the semiconductor module 100. In the present example, an interval d20 between the second narrow portion 241 and the housing portion 20 is equal to or less than the thickness t30 of the terminal 30.

In the example illustrated in FIG. 4A, the second narrow portion 241 is provided on the side opposite to the insertion direction with respect to the first wide portion 142 provided corresponding to the terminal 30, and has the width w241 greater than the width w142 of the first wide portion 142. Accordingly, in a situation where the nut holding portion 40 is inserted into the housing portion 20, the terminal 30 can be sandwiched between the second narrow portion 241 and the locking portion 21, and the terminal 30 and the nut 45 can be brought into the positional alignment in the insertion direction.

In the example illustrated in FIG. 4A, an adhesive 60 is applied to a side surface of the nut holding portion 40. The adhesive 60 may be a silicone-based adhesive or an epoxy-based adhesive. By applying the adhesive 60 to the side surface of the nut holding portion 40, it is possible to fill the groove formed when the nut holding portion 40 is inserted into the housing portion 20, and it is possible to further improve the corrosion resistance of the semiconductor module 100.

FIG. 4B is a modification of the enlarged view of the vicinity of the region A in FIG. 1A. Differences from FIG. 4A will be described with reference to FIG. 4B.

In the example of FIG. 4B, the locking member 25 includes the locking portion 21, the main body 22 which is connected to the locking portion 21 and provided along the terminal 30, and a protrusion portion 23 which protrudes from the main body 22 and locks the terminal 30 on a side surface opposite to a side surface on which the terminal 30 is locked by the locking portion 21. In the example of FIG. 4B, in the terminal 30, an insertion direction side (a positive side in the X axis direction in FIG. 4B) is locked by the locking portion 21, and a side opposite to the insertion direction (a negative side in the X axis direction in FIG. 4B) is locked by the protrusion portion 23. Accordingly, both sides of the terminal 30 in the insertion direction can be locked to suppress a positional deviation of the terminal 30.

A protrusion length L23 of the protrusion portion 23 is shorter than a protrusion length L21 of the locking portion 21. Accordingly, the nut holding portion 40 can be inserted into the housing portion 20 without interfering with the housing portion 20. The protrusion length L23 of the protrusion portion 23 may be equal to or less than the thickness t30 of the terminal 30. By reducing the protrusion length L23 of the protrusion portion 23, it is possible to suppress peeling of the adhesive 60 applied to the side surface of the nut holding portion 40 when the nut holding portion 40 is inserted into the housing portion 20, while locking the terminal 30.

The protrusion length L23 of the protrusion portion 23 may be greater than 0 mm and may be equal to or less than the thickness t30 of the terminal 30. In an example, the protrusion length L23 of the protrusion portion 23 is greater than 0 mm and equal to or less than 0.8 mm. When the protrusion length L23 of the protrusion portion 23 is 0 mm, it corresponds to the example illustrated in FIG. 2.

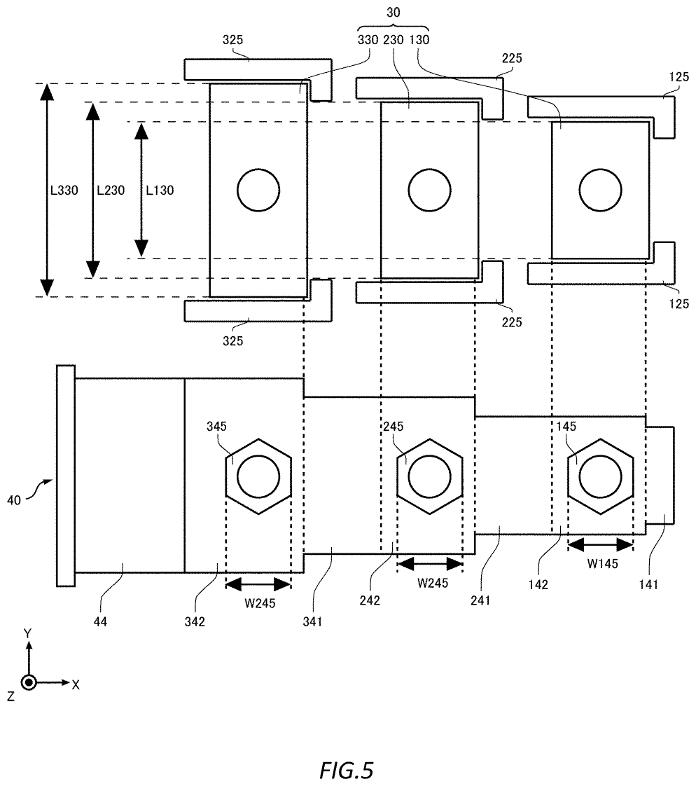

FIG. 5 is a diagram illustrating a positional relationship between the terminal 30 and the nut holding portion 40 in top view of FIG. 1A. Differences from the examples described with reference to FIGS. 2 to 4B will be described with reference to FIG. 5.

The semiconductor module 100 of the present example includes a plurality of terminals 30. In the example illustrated in FIG. 5, the plurality of terminals 30 include three terminals of a first terminal portion 130, a second terminal portion 230, and a third terminal portion 330. The semiconductor module 100 may include a plurality of locking members 25 corresponding to the plurality of terminals 30. In the example illustrated in FIG. 5, three locking members 125, 225, and 325 are provided corresponding to the first terminal portion 130, the second terminal portion 230, and the third terminal portion 330.

The nut holding portion 40 of the present example includes a plurality of nuts 45 which are brought into positional alignment with the plurality of terminals 30. In the example illustrated in FIG. 5, the nut holding portion 40 includes three nuts 145, 245, and 345 corresponding to the first terminal portion 130, the second terminal portion 230, and the third terminal portion 330.

In the example shown in FIG. 5, the second terminal portion 230 is provided on a side opposite to the insertion direction with respect to the first terminal portion 130. A length L130 of the first terminal portion 130 is shorter than a length L230 of the second terminal portion 230. That is, in a width direction perpendicular to the insertion direction, a width of the first terminal portion 130 is narrower than a width of the second terminal portion 230.

The third terminal portion 330 may be provided on a side opposite to the insertion direction with respect to the second terminal portion 230, and the length L230 of the second terminal portion 230 may be shorter than a length L330 of the third terminal portion 330. When the semiconductor module 100 includes a plurality of terminals 30, the plurality of terminals 30 may be arranged such that the lengths thereof decrease in the insertion direction. Accordingly, the nut holding portion 40 can be inserted into the housing portion 20 without interfering with the housing portion 20 and the terminal 30.

The nut holding portion 40 has a stepped shape which narrows in width stepwisely in the insertion direction. The nut holding portion 40 may have a stepped shape which narrows in width stepwisely at a same number of steps as a number of the terminals 30 provided in the semiconductor module 100, and may have a stepped shape which narrows in width stepwisely at a greater number of steps than the number of the terminals 30. The nut holding portion 40 of the present example has a shape which narrows in width stepwisely at three steps, corresponding to the same number as the number of the terminals 30, excluding a handle portion 44.

The nut holding portion 40 includes the first narrow portion 141 and the first wide portion 142 which is provided on the side opposite to the insertion direction with respect to the first narrow portion 141 and has a width greater than that of the first narrow portion 141. In the semiconductor module 100 of the present example, in a state where the nut holding portion 40 is inserted into the housing portion 20, the locking member 125 having locked the first terminal portion 130 comes into contact with and locks the first wide portion 142, whereby the nut 145 and the first terminal portion 130 are brought into positional alignment.

The nut holding portion 40 includes the second narrow portion 241 and the second wide portion 242 which is provided on a side opposite to the insertion direction with respect to the second narrow portion 241 and having a width greater than that of the second narrow portion 241. The second narrow portion 241 is provided on the side opposite to the insertion direction with respect to the first wide portion 142. The width of the second narrow portion 241 may be equal to or greater than the width of the first wide portion 142. In the example shown in FIG. 5, the width of the second narrow portion 241 is the same as that of the first wide portion 142. In the semiconductor module 100 of the present example, in a state where the nut holding portion 40 is inserted into the housing portion 20, the locking member 225 having locked the second terminal portion 230 comes into contact with and locks the second wide portion 242, whereby the nut 245 and the second terminal portion 230 are brought into positional alignment.

The first wide portion 142 may be provided corresponding to the first terminal portion 130. That is, in a state where the nut holding portion 40 is inserted into the housing portion 20, the first terminal portion 130 may cover the first wide portion 142. Similarly, the second wide portion 242 may be provided corresponding to the second terminal portion 230. That is, in a state where the nut holding portion 40 is inserted into the housing portion 20, the second terminal portion 230 may cover the second wide portion 242. Accordingly, in a state where the nut holding portion 40 is inserted into the housing portion 20, the terminal 30 and the nut 45 provided corresponding to the terminal 30 can be reliably brought into positional alignment.

The nut holding portion 40 may further include a third narrow portion 341 and a third wide portion 342. The third narrow portion 341 may be provided on a side opposite to the insertion direction with respect to the second wide portion 242, and the third wide portion 342 may be provided on a side opposite to the insertion direction with respect to the third narrow portion 341. A width of the third narrow portion 341 may be equal to or greater than a width of the second wide portion 242, and a width of the third wide portion 342 is greater than the width of the third narrow portion 341. In the semiconductor module 100, in a state where the nut holding portion 40 is inserted into the housing portion 20, the locking member 325 having locked the third terminal portion 330 may come into contact with and lock the third wide portion 342, whereby the nut 345 and the third terminal portion 330 are brought into positional alignment.

When the semiconductor module 100 includes four or more terminals 30, the nut holding portion 40 may include one or more additional narrow portions and one or more additional wide portions. Accordingly, even when the semiconductor module 100 includes a plurality of terminals 30, without interfering with the housing portion 20 and the terminals 30, the nut holding portion 40 can be inserted into the housing portion 20, whereby each of the plurality of terminals 30 is brought into positional alignment with the corresponding nut 45.

The nut 45 has a predetermined width in the insertion direction. The nut 145 may have a first width W145, the nut 245 may have a second width W245, and the nut 345 may have a third width W345. The widths of the nuts 45 in the insertion direction may be the same or different.

In the nut holding portion 40 of the present example, all locations, corresponding to the first width W145 of the nut 145, in the first wide portion 142 are narrower in width in the width direction perpendicular to the insertion direction compared to all locations, corresponding to the second width W245 of the nut 245, in the second wide portion 242. Similarly, all locations, corresponding to the second width W245 of the nut 245, in the second wide portion 242 are narrower in width in the width direction compared to all locations, corresponding to the third width W345 of the nut 345, in the third wide portion 342. Accordingly, when an adhesive 65 is applied to the side surface of the nut holding portion 40, it is possible to suppress detachment of the adhesive 65 when the nut holding portion 40 is inserted into the housing portion 20.

The handle portion 44 is provided at an end portion of the nut holding portion 40 on the side opposite to the insertion direction. The handle portion 44 is a portion gripped when the nut holding portion 40 is inserted into the housing portion 20. A width of the handle portion 44 may be a maximum value of the width of the nut holding portion 40. The width of the handle portion 44 may be equal to or greater than a width of a wide portion, which is located closest to the handle portion 44, among a plurality of wide portions included in the nut holding portion 40. Accordingly, it is possible to reduce the groove formed between the nut holding portion 40 and the housing portion 20 when the nut holding portion 40 is inserted into the housing portion 20.

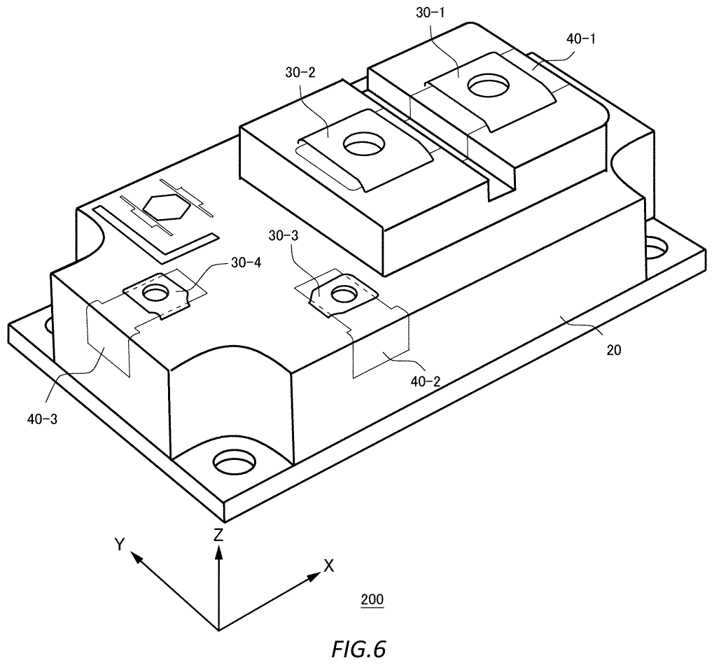

FIG. 6 is a perspective view of a semiconductor module 200 according to a modification. The semiconductor module 200 is different from the semiconductor module 100 in including a plurality of terminals 30-1, 30-2, 30-3, and 30-4 having different shapes and sizes, and a plurality of nut holding portions 40-1, 40-2, and 40-3 having different shapes and sizes.

When the semiconductor module 200 includes a plurality of nut holding portions 40, the insertion directions of the nut holding portions 40 may be the same or different. In the example illustrated in FIG. 6, an insertion direction of the nut holding portion 40-1 is the negative side in the X axis direction, an insertion direction of the nut holding portion 40-2 is a positive side in a Y axis direction, and an insertion direction of the nut holding portion 40-3 is the positive side in the X axis direction.

The terminal 30-1 and the terminal 30-2 may be main terminals of the semiconductor module 200. As an example, the terminal 30-1 is a collector terminal and the terminal 30-2 is an emitter terminal. The nut holding portion 40-1 may include two nuts which are brought into positional alignment with the terminal 30-1 and the terminal 30-2, respectively. As described above, the nut holding portion 40-1 may have a stepped shape which narrows in width stepwisely in the insertion direction.

The terminal 30-3 and the terminal 30-4 may be auxiliary external terminals of the semiconductor module 200. As an example, the terminal 30-3 is an auxiliary gate external terminal and the terminal 30-4 is an auxiliary emitter external terminal. The nut holding portion 40-2 may include one nut which is brought into positional alignment with the terminal 30-3, and the nut holding portion 40-3 may include one nut which is brought into positional alignment with the terminal 30-4. As described above, each of the nut holding portion 40-2 and the nut holding portion 40-3 may also have a stepped shape which narrows in width stepwisely in the insertion direction.

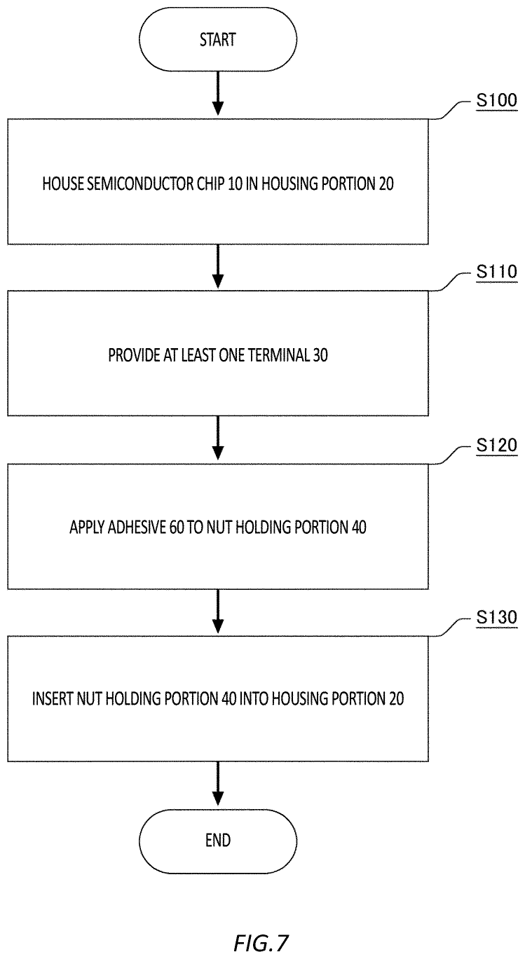

FIG. 7 illustrates an example of a flowchart of a method for manufacturing the semiconductor module 100. The method for manufacturing the semiconductor module 100 of the present example includes a step S100 of housing the semiconductor chip 10 in the housing portion 20, a step S110 of providing at least one terminal 30 electrically connected with the semiconductor chip 10, a step S120 of applying the adhesive 60 to the nut holding portion 40, and a step S130 of inserting the nut holding portion 40, which includes the nut 45 for coupling with the terminal 30, into the housing portion 20 along a predetermined insertion direction.

In step S100, the semiconductor chip 10 is housed in the housing portion 20. In step S100, a laminated substrate provided with one or more semiconductor chips 10 may be housed in the housing portion 20. Description of an internal mechanism including the semiconductor chip 10 housed in the housing portion 20 is omitted.

In step S110, the terminal 30 electrically connected with the semiconductor chip 10 is provided. The terminal 30 is connected to at least one or more semiconductor chips 10 via solder or the like. In the method for manufacturing the semiconductor module 100, when the terminal 30 is arranged at a position of the locking member 25 provided in the housing portion 20, the positions, shapes, sizes, or the like of the locking member 25 and the terminal 30 may be adjusted such that the semiconductor chip 10 housed in the housing portion 20 is arranged at an adhesion point between the terminal 30 and the laminated substrate.

In step S120, the adhesive 60 is applied to the nut holding portion 40. Step S120 of applying the adhesive 60 to the nut holding portion 40 is provided before step S130 of inserting the nut holding portion 40 into the housing portion 20. Accordingly, when the nut holding portion 40 is inserted into the housing portion 20, the groove formed between the nut holding portion 40 and the housing portion 20 can be filled with the adhesive 60, and the corrosion resistance of the semiconductor module 100 can be improved. Note that the nut holding portion 40 may be inserted into the housing portion 20 after applying the adhesive 60 to the housing portion 20 instead of applying the adhesive 60 to the nut holding portion 40.

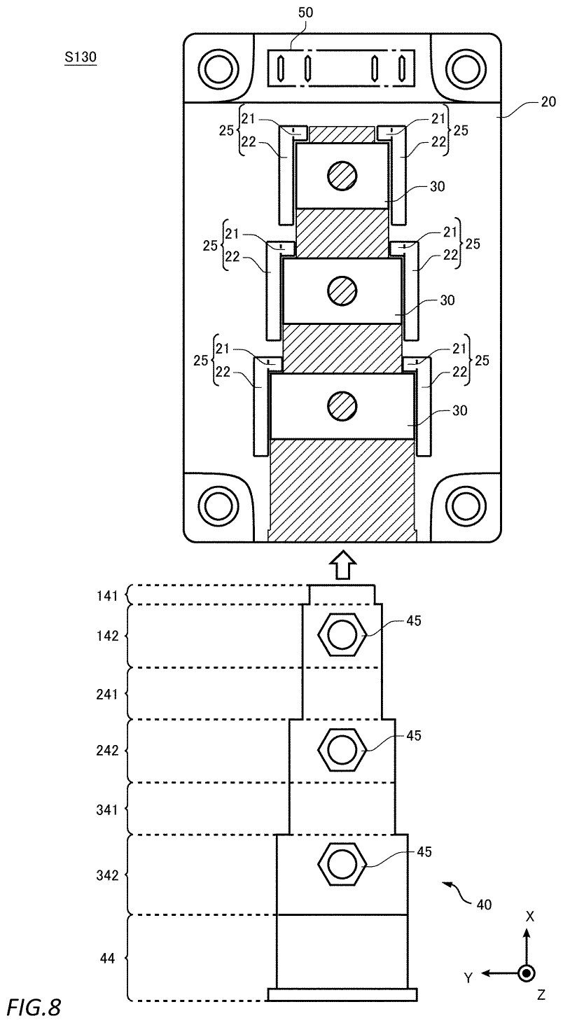

In step S130, the nut holding portion 40 is inserted into the housing portion 20. Accordingly, the nut 45 of the nut holding portion 40 and the terminal 30 are brought into positional alignment. Step S130 will be described in detail with reference to FIG. 8.

FIG. 8 illustrates an example of the upper surface in step S130 of inserting the nut holding portion 40 into the housing portion 20. The nut holding portion 40 includes the first narrow portion 141 and the first wide portion 142 having a width greater than that of the first narrow portion 141. The housing portion 20 includes the locking portion 21 which locks the nut holding portion 40 by coming into contact with the first wide portion 142.

In step S130, the nut holding portion 40 is inserted into a space provided in the housing portion 20 along the predetermined insertion direction (in FIG. 8, the X-axis positive direction). The insertion of the nut holding portion 40 may be executed by gripping the handle portion 44 of the nut holding portion 40. When the nut holding portion 40 is completely inserted into the housing portion 20, the wide portion of the nut holding portion 40 is locked by the locking portion 21 of the housing portion 20, and the positional alignment of the terminal 30 and the nut 45 is completed.

While the present invention has been described by way of the embodiments, the technical scope of the present invention is not limited to the above-described embodiments. It is apparent to persons skilled in the art that various alterations or improvements can be made to the above described embodiments. It is also apparent from description of the claims that the embodiments to which such changes or improvements are made may be included in the technical scope of the present invention.

It should be noted that each process of the operations, procedures, steps, stages, and the like performed by the device, system, program, and method shown in the claims, specification, or drawings can be executed in any order as long as the order is not indicated by “prior to”, “before”, or the like and as long as the output from a previous process is not used in a later process. Even if the operation flow is described using phrases such as “first” or “next” for the sake of convenience in the claims, specification, or drawings, it does not necessarily mean that the process must be performed in this order.

### Item 1

A semiconductor module including:
a housing portion which houses a semiconductor chip;
at least one terminal which is electrically connected with the semiconductor chip; and
a nut holding portion which includes a nut for coupling with the terminal and is inserted into the housing portion along a predetermined insertion direction, in which
the nut holding portion includes a first narrow portion and a first wide portion which is provided on a side opposite to the insertion direction with respect to the first narrow portion and has a width greater than a width of the first narrow portion, and
the housing portion includes a locking portion which locks the nut holding portion by coming into contact with the first wide portion.

### Item 2

The semiconductor module according to item 1, in which
the locking portion locks the terminal and brings the terminal and the nut into positional alignment in the insertion direction.

### Item 3

The semiconductor module according to item 1, in which
the nut holding portion has a stepped shape which narrows in width stepwisely in the insertion direction.

### Item 4

The semiconductor module according to item 1, in which
the nut holding portion includes
a second narrow portion which is provided on a side opposite to the insertion direction with respect to the first wide portion, and
a second wide portion which is provided on a side opposite to the insertion direction with respect to the second narrow portion and has a width greater than a width of the second narrow portion, and
the width of the second narrow portion is equal to or greater than the width of the first wide portion.

### Item 5

The semiconductor module according to item 4, in which
the width of the second narrow portion is greater than the width of the first wide portion.

### Item 6

The semiconductor module according to item 5, in which
the first wide portion is arranged at a position corresponding to the terminal in the insertion direction, and
the second narrow portion is arranged on a side opposite to the insertion direction with respect to the terminal in the insertion direction.

### Item 7

The semiconductor module according to item 6, in which
the terminal is sandwiched between the second narrow portion and the locking portion so that the terminal and the nut are brought into positional alignment in the insertion direction.

### Item 8

The semiconductor module according to item 6, in which
an interval between the second narrow portion and the housing portion is equal to or less than a thickness of the terminal.

### Item 9

The semiconductor module according to item 1, in which
the locking portion is provided on a side of the insertion direction with respect to the terminal,
the housing portion includes
a locking member including
the locking portion,
a main body which is connected to the locking portion and provided along the terminal, and
a protrusion portion which protrudes from the main body and locks the terminal on a side surface opposite to a side surface on which the terminal is locked by the locking portion, and
a protrusion length of the protrusion portion is shorter than a protrusion length of the locking portion.

### Item 10

The semiconductor module according to item 9, in which
the protrusion length of the protrusion portion is equal to or less than a thickness of the terminal.

### Item 11

The semiconductor module according to item 9, in which
locking members, including the locking member, are provided on both sides of the terminal, and
the width of the first wide portion is less than an interval between main bodies, including the main body, of the locking members provided on the both sides of the terminal, and is greater than an interval between locking portions, including the locking portion, of the locking members.

### Item 12

The semiconductor module according to any one of items 1 to 11, in which
the semiconductor module includes a plurality of terminals, and
the nut holding portion includes a plurality of nuts which are brought into positional alignment with the plurality of terminals.

### Item 13

The semiconductor module according to item 12, in which
the plurality of terminals include
a first terminal portion, and
a second terminal portion which is provided on a side opposite to the insertion direction with respect to the first terminal portion, and
a length of the first terminal portion is shorter than a length of the second terminal portion.

### Item 14

The semiconductor module according to any one of items 1 to 11, in which
an adhesive is applied to a side surface of the nut holding portion.

### Item 15

A method for manufacturing a semiconductor module, the method including:
housing a semiconductor chip in a housing portion;
providing at least one terminal electrically connected with the semiconductor chip; and
inserting a nut holding portion including a nut for coupling with the terminal into the housing portion along a predetermined insertion direction, in which
the nut holding portion includes a first narrow portion and a first wide portion having a width greater than a width of the first narrow portion, and
the housing portion includes a locking portion which locks the nut holding portion by coming into contact with the first wide portion.

### Item 16

The method for manufacturing a semiconductor module according to item 15, including
applying an adhesive to the nut holding portion before the inserting.

### Item 17

A semiconductor module including:
a housing portion which houses a first semiconductor chip and a second semiconductor chip;
a first terminal which is electrically connected with the first semiconductor chip;
a second terminal which is electrically connected with the second semiconductor chip; and
a nut holding portion which includes a first nut for coupling with the first terminal and a second nut for coupling with the second terminal and is inserted into the housing portion along a predetermined insertion direction, in which
the nut holding portion includes a first wide portion and a second wide portion which is provided on a side opposite to the insertion direction with respect to the first wide portion, and has a width greater than a width of the first wide portion,
in a width direction perpendicular to the insertion direction, a width of the first terminal is narrower than a width of the second terminal, and
the first terminal covers the first wide portion, and the second terminal covers the second wide portion.

### Item 18

The semiconductor module according to item 17, in which
the first nut has a first width in the insertion direction, and the second nut has a second width in the insertion direction, and
in the nut holding portion, all locations, corresponding to the first width, in the first wide portion are narrower in width in the width direction compared to all locations, corresponding to the second width, in the second wide portion.

### Item 19

The semiconductor module according to item 18, in which
the housing portion includes a locking portion which locks the nut holding portion by coming into contact with the first wide portion.

### Item 20

The semiconductor module according to item 19, in which
the nut holding portion includes
a first narrow portion which is provided on a side of the insertion direction with respect to the first wide portion, and
a second narrow portion which is provided between the second wide portion and the first wide portion and has a width less than a width of the second wide portion, and
in the width direction, the width of the second narrow portion is equal to or greater than the width of the first wide portion.

### Item 21

The semiconductor module according to item 20, in which
in the width direction, the width of the second narrow portion is greater than the width of the first wide portion.

### Item 22

The semiconductor module according to item 21, in which
the first wide portion is arranged at a position corresponding to the first terminal in the insertion direction, and
the second narrow portion is arranged on a side opposite to the insertion direction with respect to the first terminal in the insertion direction.

### Item 23

The semiconductor module according to item 21, in which
in the width direction, an interval between the second narrow portion and the housing portion is equal to or less than a thickness of the first terminal.

### Item 24

The semiconductor module according to item 19, in which
the locking portion is provided on a side of the insertion direction with respect to the first terminal,
the housing portion includes
a locking member including
the locking portion,
a main body which is connected to the locking portion and provided along the first terminal, and
a protrusion portion which protrudes from the main body and locks the first terminal on a side surface opposite to a side surface on which the first terminal is locked by the locking portion, and
in the width direction, a protrusion length of the protrusion portion is shorter than a protrusion length of the locking portion.

### Item 25

The semiconductor module according to item 24, in which
the protrusion length of the protrusion portion is equal to or less than a thickness of the first terminal.

### Item 26

The semiconductor module according to item 24, in which
locking members, including the locking member, are provided on both sides of the first terminal, and
in the width direction, the width of the first wide portion is less than an interval between main bodies, including the main body, of the locking members provided on the both sides of the first terminal, and is greater than an interval between locking portions, including the locking portion, of the locking members.

### Item 27

The semiconductor module according to any one of items 17 to 26, in which
an adhesive is applied to a side surface of the nut holding portion.

EXPLANATION OF REFERENCES

10: semiconductor chip; 11: substrate; 12: heat dissipation plate; 13: solder; 20: housing
portion; 21: locking portion; 22: main body; 23: protrusion portion; 25: locking member; 30:
terminal; 40: nut holding portion; 44: handle portion; 45: nut; 50: external connection terminal; 60:
adhesive; 100: semiconductor module; 125: locking member; 130: first terminal portion; 141: first
narrow portion; 142: first wide portion; 145: nut; 200: semiconductor module; 225: locking
member; 230: second terminal portion; 241: second narrow portion; 242: second wide portion;
245: nut; 325: locking member; 330: third terminal portion; 341: third narrow portion; 342: third
wide portion; 345: nut; 500: semiconductor module; 520: housing portion; 525: locking member;
530: terminal; and 540: nut holding portion.

What is claimed is:

1. A semiconductor module comprising:
a housing portion which houses a semiconductor chip;
at least one terminal which is electrically connected with the semiconductor chip; and
a nut holding portion which includes a nut for coupling with the terminal and is inserted into the housing portion along a predetermined insertion direction, wherein
the nut holding portion includes a first narrow portion and a first wide portion which is provided on a side opposite to the insertion direction with respect to the first narrow portion and has a width greater than a width of the first narrow portion, and
the housing portion includes a locking portion which locks the nut holding portion by coming into contact with the first wide portion.

2. The semiconductor module according to claim 1, wherein
the locking portion locks the terminal and brings the terminal and the nut into positional alignment in the insertion direction.

3. The semiconductor module according to claim 1, wherein
the nut holding portion has a stepped shape which narrows in width stepwisely in the insertion direction.

4. The semiconductor module according to claim 1, wherein
the nut holding portion includes
a second narrow portion which is provided on a side opposite to the insertion direction with respect to the first wide portion, and
a second wide portion which is provided on a side opposite to the insertion direction with respect to the second narrow portion and has a width greater than a width of the second narrow portion, and
the width of the second narrow portion is equal to or greater than the width of the first wide portion.

5. The semiconductor module according to claim 4, wherein
the width of the second narrow portion is greater than the width of the first wide portion,
the first wide portion is arranged at a position corresponding to the terminal in the insertion direction,
the second narrow portion is arranged on a side opposite to the insertion direction with respect to the terminal in the insertion direction, and
the terminal is sandwiched between the second narrow portion and the locking portion so that the terminal and the nut are brought into positional alignment in the insertion direction.

6. The semiconductor module according to claim 5, wherein
an interval between the second narrow portion and the housing portion is equal to or less than a thickness of the terminal.

7. The semiconductor module according to claim 1, wherein
the locking portion is provided on a side of the insertion direction with respect to the terminal,
the housing portion includes
a locking member including
the locking portion,
a main body which is connected to the locking portion and provided along the terminal, and
a protrusion portion which protrudes from the main body and locks the terminal on a side surface opposite to a side surface on which the terminal is locked by the locking portion,
a protrusion length of the protrusion portion is shorter than a protrusion length of the locking portion, and
the protrusion length of the protrusion portion is equal to or less than a thickness of the terminal.

8. The semiconductor module according to claim 7, wherein
locking members, including the locking member, are provided on both sides of the terminal, and
the width of the first wide portion is less than an interval between main bodies, including the main body, of the locking members provided on the both sides of the terminal, and is greater than an interval between locking portions, including the locking portion, of the locking members.

9. The semiconductor module according to claim 1, wherein
the semiconductor module includes a plurality of terminals,
the nut holding portion includes a plurality of nuts which are brought into positional alignment with the plurality of terminals,
the plurality of terminals include
a first terminal portion, and
a second terminal portion which is provided on a side opposite to the insertion direction with respect to the first terminal portion, and
a length of the first terminal portion is shorter than a length of the second terminal portion.

10. The semiconductor module according to claim 1, wherein
an adhesive is applied to a side surface of the nut holding portion.

11. A method for manufacturing a semiconductor module, the method comprising:
housing a semiconductor chip in a housing portion;
providing at least one terminal electrically connected with the semiconductor chip; and
inserting a nut holding portion including a nut for coupling with the terminal into the housing portion along a predetermined insertion direction, wherein
the nut holding portion includes a first narrow portion and a first wide portion having a width greater than a width of the first narrow portion, and
the housing portion includes a locking portion which locks the nut holding portion by coming into contact with the first wide portion.

12. The method for manufacturing a semiconductor module according to claim 11, comprising
applying an adhesive to the nut holding portion before the inserting.

13. A semiconductor module comprising:
a housing portion which houses a first semiconductor chip and a second semiconductor chip;
a first terminal which is electrically connected with the first semiconductor chip;
a second terminal which is electrically connected with the second semiconductor chip; and
a nut holding portion which includes a first nut for coupling with the first terminal and a second nut for coupling with the second terminal and is inserted into the housing portion along a predetermined insertion direction, wherein
the nut holding portion includes a first wide portion and a second wide portion which is provided on a side opposite to the insertion direction with respect to the first wide portion, and has a width greater than a width of the first wide portion,
in a width direction perpendicular to the insertion direction, a width of the first terminal is narrower than a width of the second terminal, and
the first terminal covers the first wide portion, and the second terminal covers the second wide portion.

14. The semiconductor module according to claim 13, wherein
the first nut has a first width in the insertion direction, and the second nut has a second width in the insertion direction,
in the nut holding portion, all locations, corresponding to the first width, in the first wide portion are narrower in width in the width direction compared to all locations, corresponding to the second width, in the second wide portion, and
the housing portion includes a locking portion which locks the nut holding portion by coming into contact with the first wide portion.

15. The semiconductor module according to claim 13, wherein
the nut holding portion includes
a first narrow portion which is provided on a side of the insertion direction with respect to the first wide portion, and
a second narrow portion which is provided between the second wide portion and the first wide portion and has a width less than a width of the second wide portion, and
in the width direction, the width of the second narrow portion is equal to or greater than the width of the first wide portion.

16. The semiconductor module according to claim 15, wherein
in the width direction, the width of the second narrow portion is greater than the width of the first wide portion,
the first wide portion is arranged at a position corresponding to the first terminal in the insertion direction, and
the second narrow portion is arranged on a side opposite to the insertion direction with respect to the first terminal in the insertion direction.

17. The semiconductor module according to claim 16, wherein
in the width direction, an interval between the second narrow portion and the housing portion is equal to or less than a thickness of the first terminal.

18. The semiconductor module according to claim 14, wherein
the locking portion is provided on a side of the insertion direction with respect to the first terminal,
the housing portion includes
a locking member including
the locking portion,
a main body which is connected to the locking portion and provided along the first terminal, and
a protrusion portion which protrudes from the main body and locks the first terminal on a side surface opposite to a side surface on which the first terminal is locked by the locking portion,
in the width direction, a protrusion length of the protrusion portion is shorter than a protrusion length of the locking portion, and
the protrusion length of the protrusion portion is equal to or less than a thickness of the first terminal.

19. The semiconductor module according to claim 18, wherein
locking members, including the locking member, are provided on both sides of the first terminal, and
in the width direction, the width of the first wide portion is less than an interval between main bodies, including the main body, of the locking members provided on the both sides of the first terminal, and is greater than an interval between locking portions, including the locking portion, of the locking members.

20. The semiconductor module according to claim 13, wherein
an adhesive is applied to a side surface of the nut holding portion.
